(19) United States
(12) Patent Application Publication
(10) Pub. No.: US 2025/0329989 A1
(43) Pub. Date: Oct. 23, 2025

(54) High-Power Optical Gain Waveguides

(71) Applicant: Beacon Photonics Inc., Arlington, VA (US)

(72) Inventors: Christopher Vincent Poulton, Arlington, VA (US); Michael Grey Wood, Washington, DC (US); Gordon Arthur Keeler, Falls Church, VA (US)

(73) Assignee: Beacon Photonics Inc., Arlington, VA (US)

(21) Appl. No.: 19/187,727

(22) Filed: Apr. 23, 2025

Related U.S. Application Data
(60) Provisional application No. 63/637,645, filed on Apr. 23, 2024.

(51) Int. Cl. H01S 5/20; H01S 5/30

(52) U.S. Cl. CPC H01S 5/2018; H01S 5/305

(57) ABSTRACT

High-power, integrated optical amplifiers are described in which gain waveguides of the amplifiers are designed to improve power performance by reducing power saturation effects in the amplifier. The gain waveguides can change, in at least one aspect, along the length of the gain waveguide to reduce gain saturation. Multi-mode optical beams and/or multi-stage amplification can also be employed to reduce gain saturation.

### CROSS-REFERENCE TO RELATED APPLICATIONS

The present application claims a priority benefit, under 35 U.S.C. § 119(e), to U.S. provisional application Ser. No. 63/637,645, filed on Apr. 23, 2024, entitled “High-Power Optical Gain Waveguides,” which provisional application is incorporated by reference herein in its entirety.

### FIELD OF THE DISCLOSURE

The present disclosure relates to optical systems and methods that enable increased signal output power from integrated optical gain waveguides.

### BACKGROUND

Integrated photonics enables the fabrication of on-chip optical waveguides and components. Passive and active components such as splitters, couplers, gratings, modulators, phase shifters, and photodetectors are commonly used in various material platforms. Integrated lasers and optical amplifiers are limited to certain material platforms and do not reach the performance of their fiber or free-space counterparts.

Specifically, the output power of optical gain waveguides within integrated lasers and amplifiers has been limited due to limited signal gain, pump saturation, pump depletion, signal background (linear) loss, and nonlinear signal and pump losses. To compete with fiber-based lasers and amplifiers, integrated gain waveguides need to increase output power capability.

### SUMMARY

An integrated photonics platform enables more flexibility in device design and functionalities than fiber optics due to its lithographically defined waveguides and compatibility with many microfabrication processes. Utilizing this flexibility, integrated photonics platforms can be designed to include integrated optical amplifiers that enable large output powers. Some implementations of these integrated optical amplifiers comprise gain waveguides that changes along their length to mitigate certain saturation effects. Some implementations comprise gain waveguides with multiple spatial modes or weakly confined radiation. These gain waveguides can be combined in some amplifier configurations. Further aspects of the gain waveguides, coupling to the gain waveguides, use of multi-mode beams, multi-stage optical amplifiers, multi-channel optical amplifiers, and related methods are described herein.

Some implementations relate to integrated optical amplifiers. Such optical amplifiers can comprise a substrate and a first waveguide integrated with the substrate and having a gain section of length L_{g} that is doped with rare-earth ions or transition metal ions. The first waveguide can be configured to guide a pump beam and guide a signal beam and further configured to amplify the signal beam when the rare-earth ions or the transition metal ions are excited with the pump beam. Additionally, the gain section can be configured to provide an amount of gain per unit length that changes with distance along the length L_{g} of the gain section or reduce or maintain an intensity level of the signal beam along the length L_{g} of the gain section to reduce or avoid gain saturation in the gain section.

Some implementations relate to integrated optical amplifiers that comprise a substrate and a plurality of optical amplifiers disposed on the substrate. Each optical amplifier of the plurality of optical amplifiers can comprise: an input to receive at least a signal beam to be amplified; a gain waveguide coupled to the input and integrated with the substrate and having a gain section of length L_{g} that is doped with rare-earth ions or transition metal ions; and an output to output an amplified signal beam. The gain section can be configured to guide a pump beam and guide the signal beam and to amplify the signal beam, producing the amplified signal beam when the rare-earth ions or the transition metal ions are excited with the pump beam. Additionally, the gain section can be configured to provide an amount of gain per unit length that changes with distance along the length L_{g} of the gain section or reduce or maintain an intensity level of the signal beam along the length L_{g} of the gain section to reduce or avoid gain saturation in the gain section.

Some implementations relate to integrated optical amplifiers that comprise: a substrate; a first waveguide integrated with the substrate and having a gain section of length L_{g} that is doped with rare-earth ions or transition metal ions, wherein the first waveguide is configured to guide a pump beam and guide a signal beam and to amplify the signal beam when the rare-earth ions or the transition metal ions are excited with the pump beam; and a second waveguide integrated with the substrate and having a section parallel to the gain section of the first waveguide, wherein the second waveguide is configured to evanescently couple the signal beam from the gain section along at least a portion of the length L_{g} of the gain section and thereby reduce gain saturation in the gain section.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (eg., functionally similar and/or structurally similar components).

FIG. 1 depicts an optical amplifier with an input signal, output signal, and pump beam.

FIG. 2A depicts a plan view of an optical amplifier implemented in an optical waveguide with undoped input and output regions and a doped gain region. The amplifier has an input signal, output signal, and pump beam.

FIG. 2B is an idealized plot of increasing signal power along the gain waveguide of FIG. 2A neglecting saturation.

FIG. 2C is a realistic plot of increasing signal power along the gain waveguide of FIG. 2A including power saturation effects.

FIG. 3A depicts a plan view of a waveguide optical amplifier with a tapered doped gain region.

FIG. 3B depicts a plan view of a waveguide optical amplifier with a tapered gain region comprising undoped waveguide regions on either side of a doped gain waveguide region.

FIG. 4A depicts a plan view of a waveguide optical amplifier with a tapered doped gain region.

FIG. 4B depicts a plan view of a waveguide optical amplifier with a doped gain region that includes tapered and untapered portions.

FIG. 4C depicts a plan view of a waveguide optical amplifier with a doped gain region that includes tapered input and output transition portions.

FIG. 5A depicts a plan view of a waveguide optical amplifier with varying doping levels in a series of doped gain regions.

FIG. 5B depicts a process flow to fabricate the optical amplifier depicted in FIG. 5A.

FIG. 5C depicts an alternative process flow to fabricate the optical amplifier depicted in FIG. 5A.

FIG. 6A depicts a plan view of a waveguide optical amplifier.

FIG. 6B depicts an elevation view of the optical amplifier from FIG. 6A.

FIG. 6C plots a waveguide index profile at cross-section ‘A’ from FIG. 6A and FIG. 6B.

FIG. 6D plots the waveguide mode at the signal wavelength for the index profile plotted in FIG. 6C.

FIG. 6E plots a waveguide index profile at cross-section ‘B’ from FIG. 6A and FIG. 6B.

FIG. 6F plots the waveguide mode at the signal wavelength for the index profile plotted in FIG. 6E.

FIG. 7A depicts a plan view of a waveguide optical amplifier with two waveguides to control evanescent coupling of signal and pump into and out of the doped gain region of the device.

FIG. 7B depicts a cross-sectional view of an optical amplifier with two levels of waveguides to control evanescent coupling of signal and pump into and out of the doped gain region of the device.

FIG. 8A depicts a plan view of a waveguide optical amplifier with two waveguides to control coupling of signal and pump through the doped gain region of the device.

FIG. 8B depicts a cross-sectional view of an optical amplifier with two levels of waveguides to control coupling of signal and pump through the doped gain region of the device.

FIG. 9 depicts a waveguide amplifier with a signal and pump combiner, a gain waveguide, and a signal and pump splitter.

FIG. 10 depicts a signal and pump combiner with multiple single-spatial mode pump laser diodes.

FIG. 11A depicts a signal and pump combiner with a multi-spatial-mode pump laser diode.

FIG. 11B depicts a signal and pump combiner with a multi-spatial-mode pump laser diode that utilizes a mode converter.

FIG. 12A plots a waveguide index profile.

FIG. 12B plots the waveguide mode at the signal wavelength.

FIG. 12C, FIG. 12D, FIG. 12E, and FIG. 12F plot various waveguide modes at the pump wavelength.

FIG. 13A plots a waveguide index profile.

FIG. 13B plots the waveguide mode at the signal wavelength.

FIG. 13C and 13D plots different waveguide modes at the pump wavelength.

FIG. 14A plots a waveguide index profile.

FIG. 14B plots the waveguide mode at the signal wavelength.

FIG. 14C, FIG. 14D, FIG. 14E, and FIG. 14F plot various waveguide modes at the pump wavelength.

FIG. 15A depicts an optical amplifier system comprising cascaded optical amplifier stages.

FIG. 15B depicts an optical amplifier system comprising parallel amplifier arms with a single input signal and a single output signal. Coherent combination can occur with a corresponding phase shifter for each amplifier arm or some amplifier arms.

FIG. 16A depicts an optical amplifier system comprising parallel amplifier arms with a single output signal coupled to an optical fiber through grating couplers.

FIG. 16B depicts an optical amplifier system comprising parallel amplifier arms with a single output signal coupled to a lens through grating couplers.

FIG. 16C depicts an optical amplifier system comprising parallel amplifier arms with a single output signal coupled to a lens through edge couplers.

FIG. 17A depicts an optical amplifier system comprising parallel amplifier arms. The phase of each amplifier arm can be tuned based on the detected output power.

FIG. 17B depicts an optical amplifier system comprising parallel amplifier arms. The phase of each amplifier arm can be tuned based on a photonic circuit.

FIG. 18A depicts an optical amplifier system comprising parallel amplifier arms. The amplitude profile of the single output signal is made non-uniform by variable optical attenuators, eg., for better mode matching with an optical fiber.

FIG. 18B depicts an optical amplifier system comprising parallel amplifier arms. The amplitude profile of the single output signal is made non-uniform by a non-uniform 1×N splitter, eg., for better mode matching.

FIG. 18C depicts an optical amplifier system comprising parallel amplifier arms. The amplitude profile of the single output signal is non-uniform by different gains for different amplifier arms, eg., for better mode matching.

FIG. 19A depicts an optical amplifier system comprising parallel amplifier arms with a single input signal and multiple output signals.

FIG. 19B depicts an optical amplifier system comprising parallel amplifier arms and multiple output signals coupled to a multi-mode optical fiber.

FIG. 19C depicts an optical amplifier system comprising parallel amplifier arms and multiple output signals coupled to a multi-core fiber, eg., with each output signal coupled to a different core in the multi-core fiber.

FIG. 19D depicts an optical amplifier system comprising parallel amplifier arms and multiple output signals coupled to different optical fibers through respective grating couplers.

FIG. 19E depicts an optical amplifier system comprising parallel amplifier arms and multiple output signals coupled to multiple optical fibers through edge couplers.

FIG. 20A depicts an optical amplifier system comprising parallel amplifier arms with multiple input and output signals.

FIG. 20B depicts an optical amplifier system comprising parallel amplifier arms with multiple input and output signals coupled to multi-mode optical fibers at the input and output.

FIG. 20C depicts an optical amplifier system comprising parallel amplifier arms with multiple input and output signals coupled to multi-core optical fibers at the input and output.

FIG. 20D depicts an optical amplifier system comprising parallel amplifier arms with multiple input and output signals coupled to multiple optical fibers through grating couplers at the input and output.

FIG. 20E depicts an optical amplifier system comprising parallel amplifier arms with multiple input and output signals coupled to multiple optical fibers through edge couplers at the input and output.

### DETAILED DESCRIPTION

### 1. Overview of Optical Amplifiers

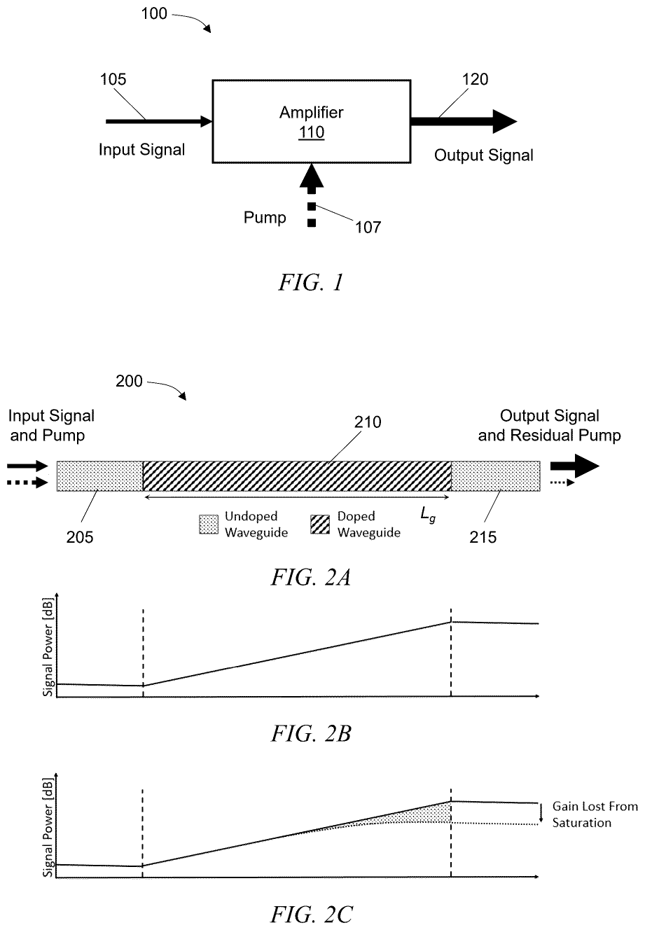

FIG. 1 depicts a block diagram of an optical amplification system 100. The system 100 comprises an optical amplifier 110 that comprises an integrated gain waveguide. The gain waveguide can be a strip, ridge, low confinement, slot, or other type of planar waveguide in an integrated photonics material platform such as silicon, silicon nitride, silicon dioxide, alumina, tantala, InP, GaN, GaAs, lithium niobate, lithium tantalate, along with others. For instance, the gain waveguide may be (1) a silicon nitride waveguide doped with one or more rare-earth ions (eg., erbium, ytterbium, thulium, neodymium, or praseodymium ions) or one or more transition metal ions (e.g., nickel, chromium, or titanium ions); (2) an InP waveguide with various quaternary compound semiconductors, such as InGaAsP and InAIGaAs layers; (3) a GaAs waveguide doped with AIGaAs quantum wells/dots; or (4) a GaN waveguide doped with GalnN quantum wells/dots. A gain waveguide core on a substrate can be clad in a bottom cladding and an optional top cladding. Suitable cladding materials for the gain waveguide include but are not limited to SiO₂, InP, GaAs, and GaN.

Optical gain in the gain waveguide is achieved through stimulated emission by excited rare-earth ions or other host dopants including titanium or chromium, semiconductor materials, or other gain media. The amplifier 110 receives an optical input signal 105, outputs an optical output signal 120, and receives a pump input 107. In some cases, the gain medium in the optical amplifier 110 can be pumped electrically, such as in semiconductor optical amplifiers (SOA) in InP, GaN, GaAs, or other material platforms. In some implementations, the gain medium of the optical amplifier 110 can be optically pumped. eg., when a rare earth or similar dopant material is used in the gain medium such as erbium, thulium, neodymium, holmium, ytterbium, or praseodymium.

FIG. 2A depicts a single gain waveguide 200 that can be used for the gain waveguide of the optical amplifier 110 of FIG. 1. Generally, the “gain waveguide” of an optical amplifier is doped (along a portion or all of the gain waveguide) with one or more atomic or chemical species to provide optical gain for a signal beam propagating along the gain waveguide when the dopant is excited (eg., with a pump beam which may also propagate along the gain waveguide). In this example, the gain waveguide 200 comprises an undoped input region 205, an undoped output region 215, and a doped gain section 210 between these two undoped regions. The gain section 210 can have a length L_{g}. An optical pump beam at a first wavelength and an optical signal beam at a second wavelength can be coupled into the input region 205 of the gain waveguide 200 through which both the pump and signal wavelengths pass with low losses and no gain. The pump beam can propagate in the same direction as the signal beam (a co-propagating pump beam), in the opposite direction (a counter-propagating pump beam), or in both the same and opposite directions (co-and counter-propagating pump beams.) Upon reaching the doped gain section 210 of the gain waveguide 200, radiation at the pump wavelength is absorbed by the dopants in the gain section 210 which allows for radiation at the signal wavelength to experience gain through stimulated emission, increasing the amplitude and intensity of the signal beam. The overall background optical loss in the gain waveguide can be no greater than 10 dB/m for the signal beam (i.e, at the wavelength of the signal beam), in some cases no greater than 5 dB/m for the signal beam, and in yet other cases no greater than 1 dB/m for the signal beam.

After passing through the doped gain section 210 of the gain waveguide 200, the amplified signal beam and residual pump beam pass through the undoped output region 215 and can be optically coupled to downstream optical systems. The residual pump beam can be filtered out using a notch filter or wavelength division multiplexer (WDM). Similarly, any amplified spontaneous emission (ASE) can be filtered using a bandpass or notch filter. M any waveguide core and cladding configurations can be used to demonstrate a waveguide amplifier like that depicted in FIG. 2A. In such implementations, as noted above, the pump beam and signal beam can be input on the same, opposite, or simultaneously on both ends of the gain waveguide 200.

Although only a gain waveguide core is depicted in FIG. 2A, the drawing here and other drawings described herein showing only waveguide cores are simplified drawings. These simplified drawings omit cladding material adjacent to the waveguide core as well as the substrate on which the waveguides are formed. It should be understood that these waveguides (core and cladding) are integrated with the substrates.

In the case of relatively weak input signals and/or smaller total gain, optical power at the signal wavelength increases exponentially in intensity throughout the doped gain section 210 of the gain waveguide 200 as indicated by the idealized plot of FIG. 2B. More intense input signals and/or larger total gain can lead to gain saturation, as indicated by the more realistic plot of FIG. 2C. In FIG. 2C, the amplifier gain decreases for higher power in the gain waveguide and the total output power no longer grows exponentially with the length of the doped gain waveguide. Note that the vertical axes of FIG. 2B and FIG. 2C are in logarithmic units so that an exponential increase in intensity is plotted as a straight line. The present technology includes several ways to reduce the impact of gain saturation.

### 2. Selective Area Doping and Mode Size Control in Gain Waveguides

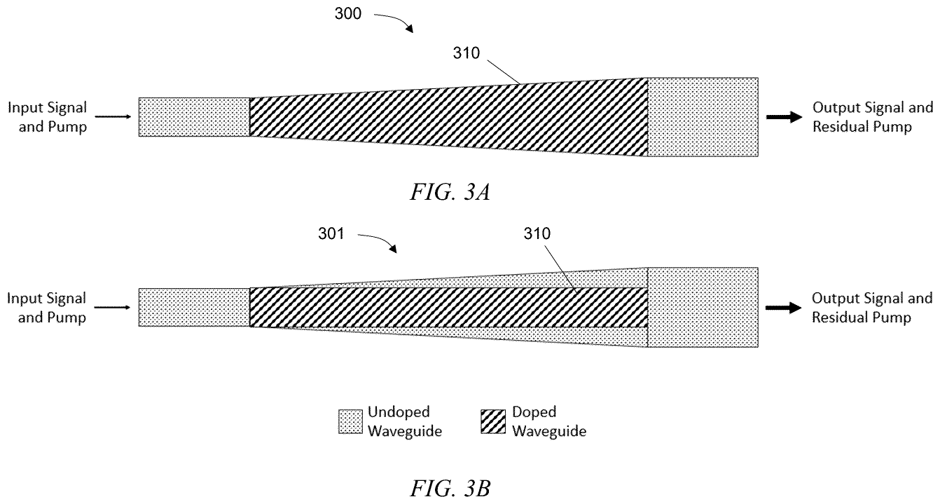

For a given gain medium with fixed-material absorption and emission cross sections and upper state lifetime, techniques for reducing the impact of gain saturation include increasing the mode area (eg., to decrease or maintain the signal intensity level along the gain section of a gain waveguide 300), decreasing the overlap of the signal radiation and waveguide core, and/or reducing or maintaining the input signal intensity level in the doped gain region. Some approaches can involve changing the gain per unit length along at least a portion of the length of the gain section 310 in a gain waveguide 300. These general prescriptions for increasing saturation power vary broadly with gain mechanism, waveguide media, wavelength, and other parameters. An implementation of a gain waveguide 300 that would increase mode area along the gain section 310 is depicted in FIG. 3A. In this example, the width of the gain section 310 increases along the length of the gain section. Other similar techniques for increasing mode area can achieve the same goal (eg., transitioning to a rib waveguide structure in which a patterned rib overlies a slab of waveguide material).

A second implementation of a gain waveguide 301 configured for increasing mode area is depicted in FIG. 3B. In this implementation, the gain section 310 is doped such that the gain section has uniform width, whereas the waveguide that includes the gain section is tapered, increasing in length along the gain waveguide 300. The design can both increases mode area while also decreasing signal overlap with the doped gain section 310 through selective doping of the gain waveguide 301.

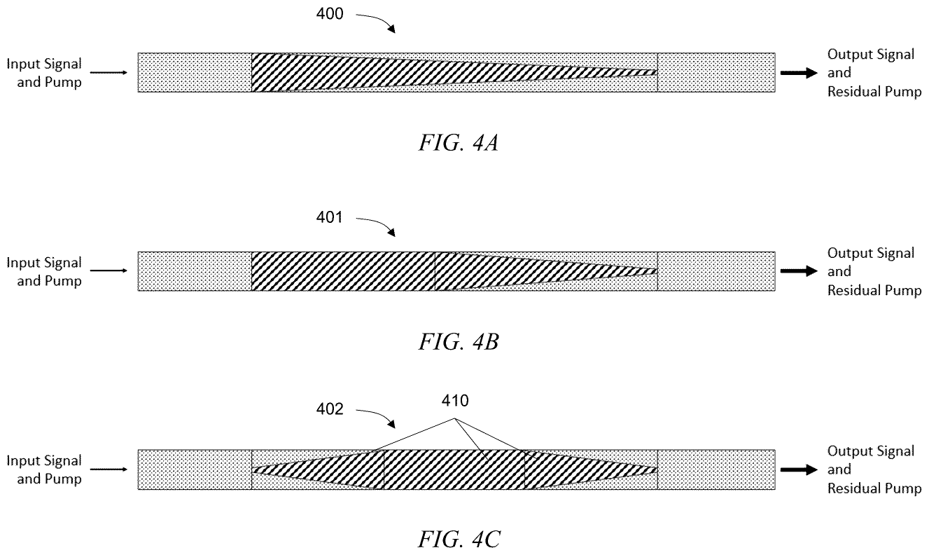

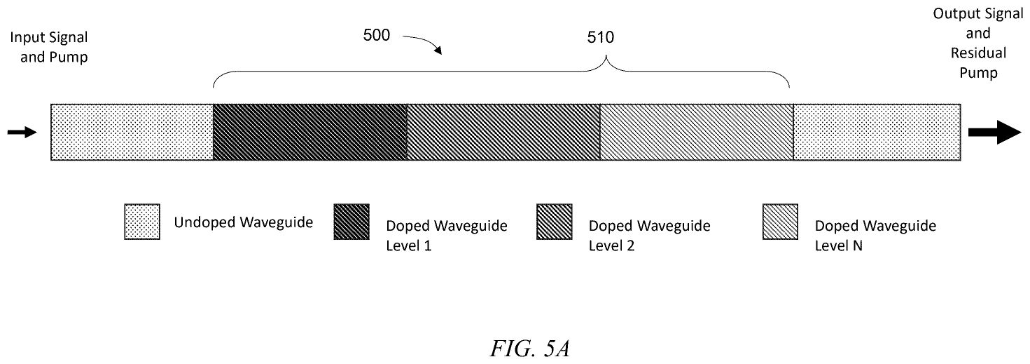

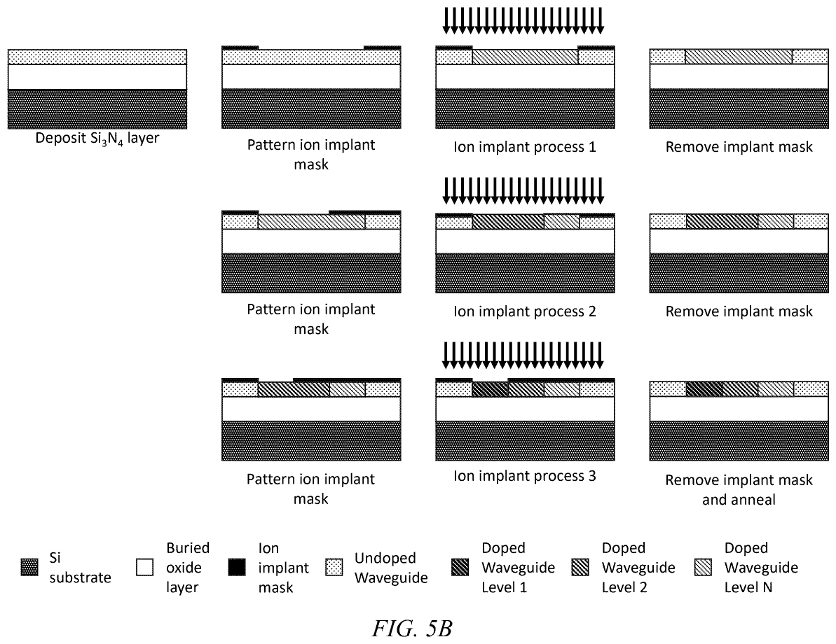

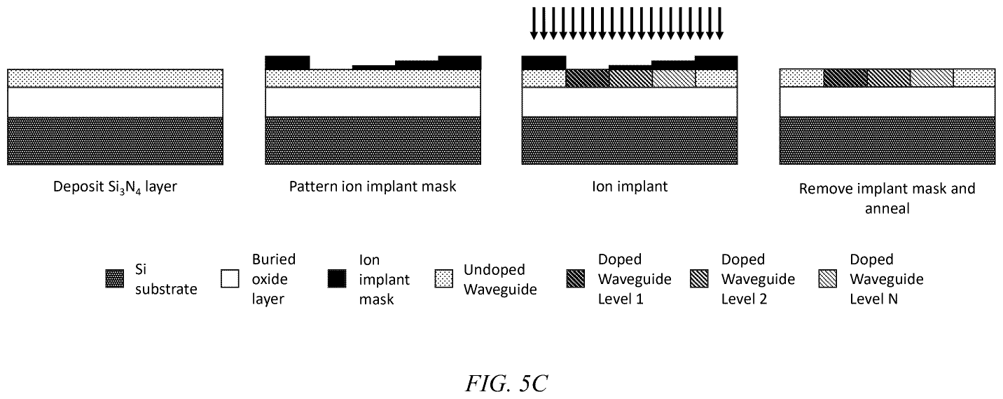

Additional implementations that use selective doping of the gain waveguide 400, 401, 402 to decrease signal overlap with the doped gain region without increasing overall mode area are depicted in FIG. 4A, FIG. 4B, and FIG. 4C. Many different patterning techniques, including incorporation of discontinuous doped regions, can be used during doping to accomplish this goal. For instance, a patterned mask can shield sections of the photonic integrated circuit during doping/ion implantation to keep some region(s) free of dopants, eg., using process steps as depicted in FIG. 5B and FIG. 5C. Additionally, as illustrated in the patterning of doped gain sections 410 in FIG. 4C, additional functionality such as mode matching to suppress reflection can be simultaneously achieved with selective gain dopant patterning along with the primary goal of increasing saturation power.

Rather than using selective area doping as in FIG. 3A through FIG. 4C, the design illustrated in FIG. 5A instead uses different doping levels (Levels 1 through N) along different sections of the gain waveguide 500 to control the overlap of the signal radiation with the optical gain region. In one implementation, the doping density is progressively decreased in each sequential segment of the gain waveguide 500 using masks during doping/ion implantation, eg., as depicted in FIG. 5B and FIG. 5C, such that the fraction of the waveguide core exposed to doping progressively decreases along the length of the waveguide core. For rare earth dopants, the doping level can vary between about 10¹⁸ cm⁻³ and about 10²¹ cm⁻³ in a stepped fashion, a smooth fashion (eg., linearly or logarithmically), or a hybrid fashion (smooth with steps).

An example fabrication process for achieving a step-wise sequential doping profile along the gain waveguide 500 is depicted in FIG. 5B. This flow comprises using at least a different ion implant mask for each doping concentration level. In some cases, a different implant recipe can be used for each doping concentration level. Some fabrication flows could achieve similar dopant profiles, such as using different ion implantation energies or dopant doses at each implant step. A second fabrication process to achieve this gain doping profile is depicted in FIG. 5C. This process can use a single ion implant mask and single ion implant step and recipe. The ion implant mask has different thicknesses along the length of the gain waveguide to vary implant concentration along the waveguide.

An extension of the concept disclosed in FIG. 5A is a continuously varying doping density along the gain section 510. Similarly, a variation of the fabrication process described in FIG. 5C can achieve this continuously varying gain dopant profile. In this alternative process, the thickness of the ion implant mask varies continuously along the length of the gain waveguide.

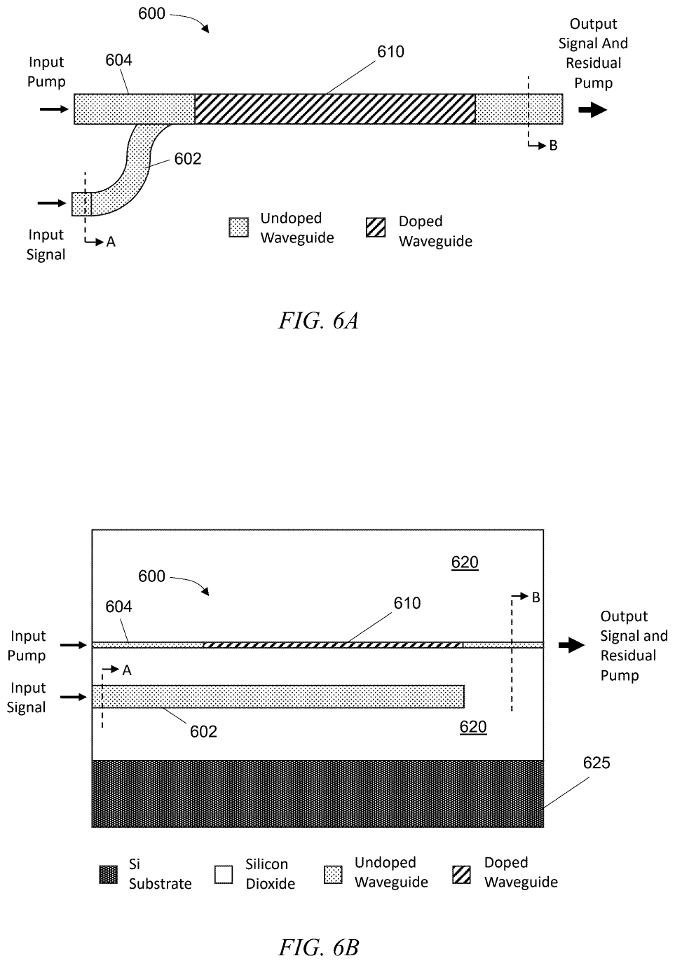

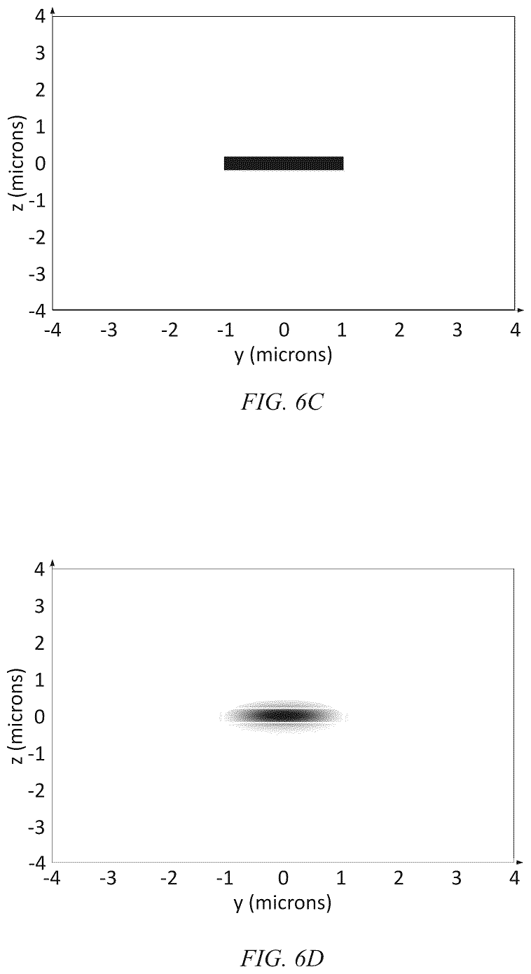

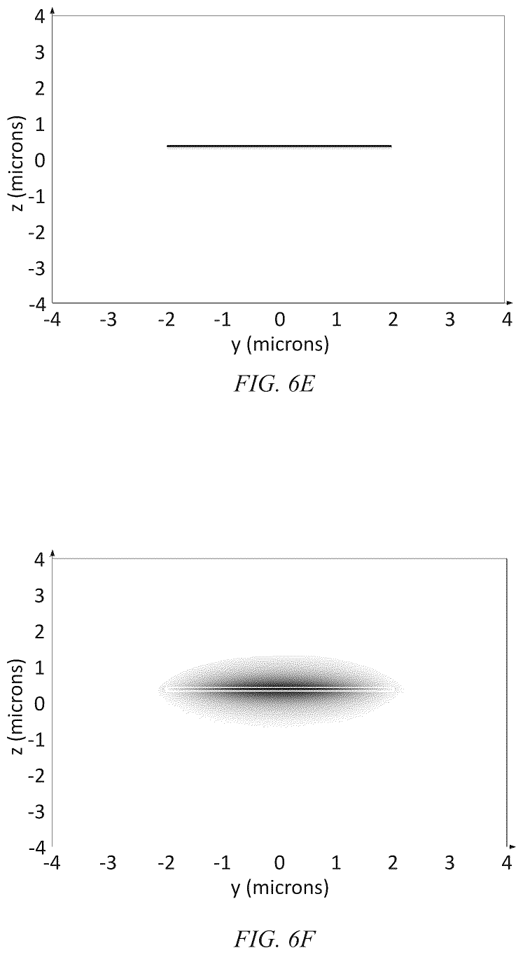

Another technique for increasing mode area and decreasing overlap of the signal radiation and doped gain section is depicted schematically in FIG. 6A and FIG. 6B in plan view and cross-sectional view, respectively. In this optical waveguide amplifier 600, a first waveguide 602 (input signal waveguide) and a second waveguide 604 (gain and output signal waveguide) formed on different fabrication levels with different mode areas and confinement factors are used such that the gain section 610 has a large mode area. Evanescent coupling between the two waveguide levels is accomplished by bringing them in close proximity to each other (eg., within one or two signal wavelengths) after being further separated elsewhere on the common substrate. (Because the pump wavelength is shorter than the signal wavelength, the pump beam should not couple as readily between the waveguides.) As depicted in FIG. 6B, these two waveguides may be at different vertical heights in the structure. The first waveguide 602 and the second waveguide 604 can be surrounded by cladding material 620 and be disposed on a substrate 625. Separating the waveguides vertically reduces the areal footprint of the gain section 610 and allows for different gain section shapes, including long spirals. Generally, vertically stacked evanescently coupled spiral waveguides occupy a smaller area than evanescently coupled spiral waveguides laid out in the same plane. Various patterning techniques such as tapers and/or gratings can be incorporated into the coupling region to increase the efficiency of coupling between the waveguides. In a different implementation, the input signal waveguide can have low confinement, and coupling could occur in-plane rather than vertically. The loss at the signal wavelength for the first waveguide 602 and for the second waveguide 604 in this implementation and other evanescently coupled waveguide implementations described below can be less than 1 dB/m.

FIG. 6C and FIG. 6E plot the refractive index profile for cross-sections ‘A’ and ‘B’ depicted in FIG. 6A and FIG. 6B, respectively. FIG. 6D and FIG. 6F plot simulated mode profiles that correspond to the index profiles in FIG. 6C and FIG. 6E, respectively, for a signal wavelength of 1550 nm. As these simulations cover the same cross-sectional area, there is a clear increase in mode size and decrease in confinement to the waveguide core of FIG. 6E for the second waveguide 604, as plotted in FIG. 6F. It should be understood that the specific geometry, refractive index profile, and wavelength used in these simulations are used as an example and other implementations are possible (for example, waveguide cores made of SiN, Si, InGaAsP, InAlGaAs, AlGaAs, or GaInN and claddings made of SiO₂, InP, GaAs, or GaN).

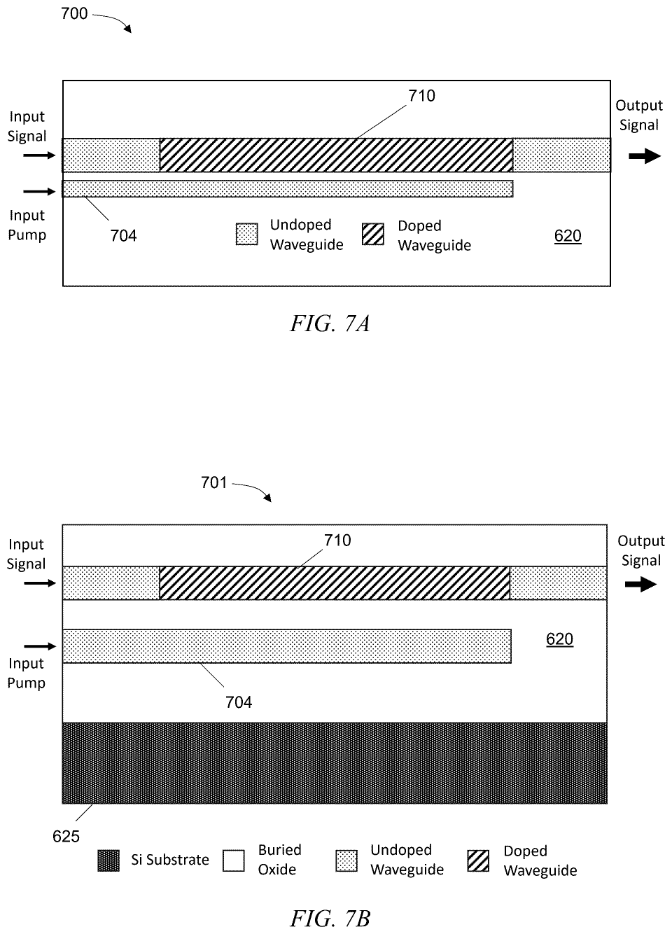

FIG. 7A illustrates an additional approach for varying the gain along the gain section 710 of a gain waveguide 700. In this implementation, pump radiation is guided by a pump waveguide 704 that runs parallel to the gain waveguide 700 along the gain section 710. The pump waveguide 704 and gain waveguide 700 can be co-planar (i.e., in the same plane) or stacked (i.e., in different planes). Pump radiation can be evanescently and continuously coupled from the pump waveguide 704 into the gain waveguide 700 along at least a portion of the gain waveguide, which can be separated from the pump waveguide 704 by about one pump wavelength along the doped gain section 710. The separation distance between the pump waveguide 704 and the gain section 710 need not be constant along the gain section (which is depicted in FIG. 7A). Further, the cross-sectional dimensions of pump waveguide 704 need not be constant along the gain section 710. The separation distance and/or cross-sectional dimensions can change along the gain section 710 to change the coupling strength and amount of optical pump power coupled into the gain section 710 as a function of distance along the gain section. In this manner, an arbitrary gain profile can be created along the gain section 710 since the power of the pump radiation coupled into the gain section at each location along the gain section is determined locally by the evanescent coupling.

Coupling pump radiation into the gain section 710 can be advantageous over the coupling arrangement shown in FIG. 2A. For that arrangement, pump radiation coupled into an end of the gain waveguide 200 is absorbed as it travels along the gain section 210, leaving less available pump power for subsequent regions of the gain section 210. As the signal strength grows, there may not be enough residual pump radiation in the gain section 210 to support further amplification of the signal, leading to the saturated gain condition plotted in FIG. 2C. In contrast, the arrangements of FIG. 7A and FIG. 7B can continuously deliver unabsorbed pump radiation to downstream portions of the gain section 710 evanescently via the pump waveguide 704. In some implementations, the amount of pump radiation delivered via the pump waveguide 704 can be tailored (e.g., by changing the evanescent coupling strength along the gain section 710) such that a larger amount of pump radiation is coupled into the gain section 710 as a function of distance along the gain section 710 travelled by the input signal to be amplified. Thus, as the signal strength grows, more pump radiation is coupled into the gain section 710 to provide higher optical gain and reduce or avoid gain saturation.

FIG. 7B depicts a similar gain waveguide 701 to FIG. 7A, though implemented with vertical rather than in-plane coupling. The implementations of FIG. 7A and FIG. 7B can be combined with other implementations described herein, such as selective area gain doping or techniques for increasing mode described above. In addition, other types of coupled waveguides including various tapered or un-tapered implementations or those in which pump coupling strength is varied along the propagation axis can achieve similar in-coupling of the pump radiation. If desired, the power saturation can be increased by modifying the gain doping, tapering, etc. of the separate pump and gain waveguides.

### 3. Coupling and Decoupling Signal and Pump Beams

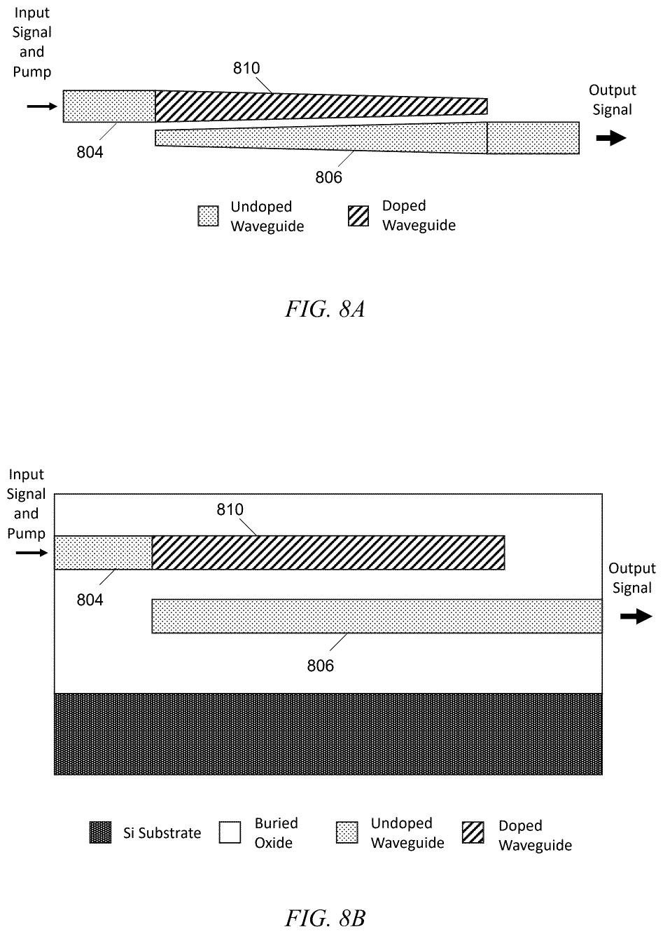

The approaches for increasing saturation power described in FIG. 3A through FIG. 7B primarily focus on designs for increasing mode area and/or decreasing the overlap of the signal radiation with the doped gain section. In contrast to these approaches, FIG. 8A depicts a coupled waveguide approach in which two tapered waveguides are evanescently coupled to each other in order to increase saturation power by decreasing signal radiation intensity in the input waveguide 804 along gain section 810. The coupling ratio can be changed by varying the widths of the waveguides and/or the distance between waveguides along the lengths of the waveguides. The input waveguide 804 comprises gain dopants along its gain section 810 while the output waveguide 806 can be undoped. With proper design of the dimensions of the waveguides and coupling gaps, radiation at the signal wavelength(s) can be evanescently coupled out of the input waveguide 804 along the gain section 810 and into the output waveguide 806. This coupling of signal radiation out of the gain section can reduce or avoid gain saturation in the gain section. By controlling the overall coupling length of this structure, it is possible to achieve efficient coupling to the output waveguide 806 and high output power.

FIG. 8B depicts an alternative implementation to couple signal radiation out of the gain section 810 which uses vertical coupling rather than in-plane coupling as in FIG. 8A. These implementations can be combined with other implementations described herein, such as selective area gain doping or techniques for increasing mode described above. In addition, other types of coupled waveguides including various tapered or un-tapered implementations can achieve similar out-coupling of the signal radiation from the gain section 810 to increase output power from the optical amplifier. For instance, the input waveguide 804 and gain section 810 may evanescently couple to a vertically (or horizontally) offset pump injection waveguide and to a horizontally (or vertically) offset signal extraction waveguide. Modifying the doping levels, doping profiles, and/or other parameters could increase the saturation power.

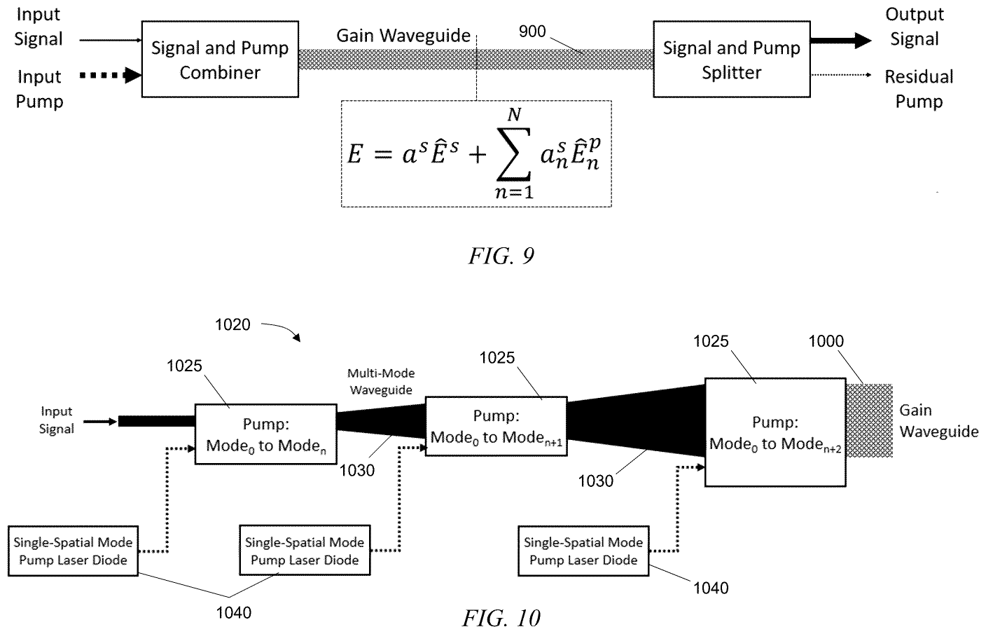

An optical amplifier can be formed with a waveguide having a gain section that contains rare earth dopants such as erbium, thulium, neodymium, holmium, ytterbium, or praseodymium in the core and/or cladding material along the gain section. In some implementations, the gain section contains transition-metal ion dopants (eg., nickel, chromium, or titanium ions). Dopants can be introduced into the waveguide through various ways such as co-sputtering with various oxides (Al₂O₃, TeO₂, SiO₂, ErO₃, etc.), atomic layer deposition, ion implantation, or ion exchange. To provide optical gain for a signal wavelength, the rare-earth ions should be optically pumped with pump radiation at a pump wavelength. This process is depicted in FIG. 9 where an input signal and input pump are combined into a gain waveguide 900. The gain waveguide 900 may support multiple spatial modes (eg., ten or fewer spatial modes), but it is beneficial for the signal and pump combiner to excite only one signal mode to ensure no gain competition. (Unwanted signal modes and/or ASE can be filtered out with a bandpass filter.) However, multiple pump modes may propagate in the gain waveguide to increase overall signal output power as described in the following paragraphs. The pump waveguide modes could consist of different order modes (e.g., TE₀₀, TE₀₁, TE₁₀, etc.) and/or different polarizations (i.e, TE, TM, and TEM), and/or different spatial distributions across cores (symmetric, antisymmetric, etc.).

FIG. 10 depicts one implementation of a signal and pump combiner 1020 that outputs a single-mode signal and multi-mode pump into a gain waveguide 1000. This combiner 1020 couples outputs from multiple pump laser diodes into the gain waveguide without frequency or phase locking (i.e., coherent combination). Such combining of pump radiation enables moderately-powered laser pump sources, which may each output a single spatial mode, to be passively combined into a single gain waveguide 1000. The combination of pump sources in this way can achieve a large total pump power in the gain waveguide 1000 and thereby produce a large signal output power from the gain waveguide 1000.

In some implementations, the different pump sources 1040 may come from different waveguides (each containing pump radiation received from one or more pump sources 1040, such as laser diodes) on a single physical die. Pump source combination can be accomplished, in some cases, by guiding the optical output from each source in a different mode within the multi-mode gain waveguide. Integrated cascaded mode converters 1025 can multiplex the pump sources onto one or more waveguides of the pump combiner 1020 that are coupled to the gain waveguide 1000 without interfering with the signal or other pump signals. The signal beam can stay in a spatial single-mode profile throughout the combiner, potentially using adiabatic tapers 1030 between the pump mode converters 1025. After multiplexing the series of pump sources 1040, the signal and multiple pump modes propagate down the length of the gain waveguide 1000 to produce the desired amplified signal power. Afterwards, a signal and pump splitter can be formed in a similar fashion with cascaded mode converters to de-multiplex residual pump radiation from each mode until only the signal remains.

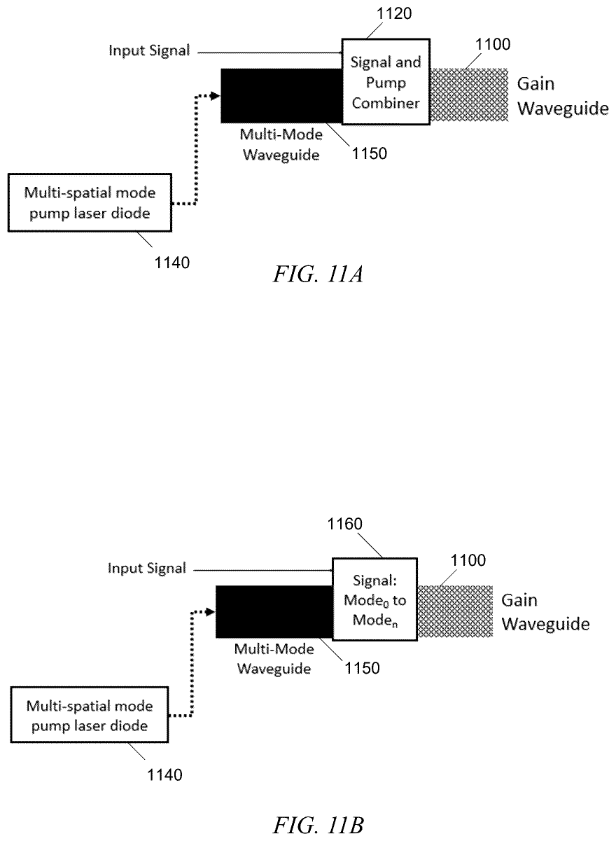

A signal and pump combiner 1120 can also be used to combine a multi-spatial-mode laser pump source 1140 and an input signal for amplification along a gain waveguide 1100, as depicted in FIG. 11A. Multi-spatial-mode laser diodes can be used to provide larger optical pump powers but can be difficult to optically couple to on chip and combine with the single-mode input signal. In the implementation of FIG. 11A, an on-chip multi-mode waveguide 1150 is coupled to the laser diode pump source to capture all optical spatial modes output from the pump source 1140. This could be done by directly butt-coupling the laser die of the pump source 1140 to a facet of the multi-mode waveguide 1150 or to the core of a multi-mode optical fiber. The input signal can be multiplexed onto the multi-mode waveguide 1150 or into the gain waveguide 1100 through a combiner 1120 or through a signal mode converter 1160 as depicted in

FIG. 11B. The signal mode converter 1160 can be designed to convert the single-mode input signal to one or more selected mode(s) of the multi-mode waveguide, such as the fundamental mode and/or a higher-order mode. In some implementations, the signal is converted to or remains in only one optical mode when output from the mode converter 1160 to the gain waveguide 1100. An optional mode filter (not shown) coupled to the output of the mode converter 1160 can suppress undesired higher-order modes if needed. The mode converter 1160 should not cut off any of the pump modes along its length, which could occur if the multi-mode waveguide 1150 is significantly narrowed.

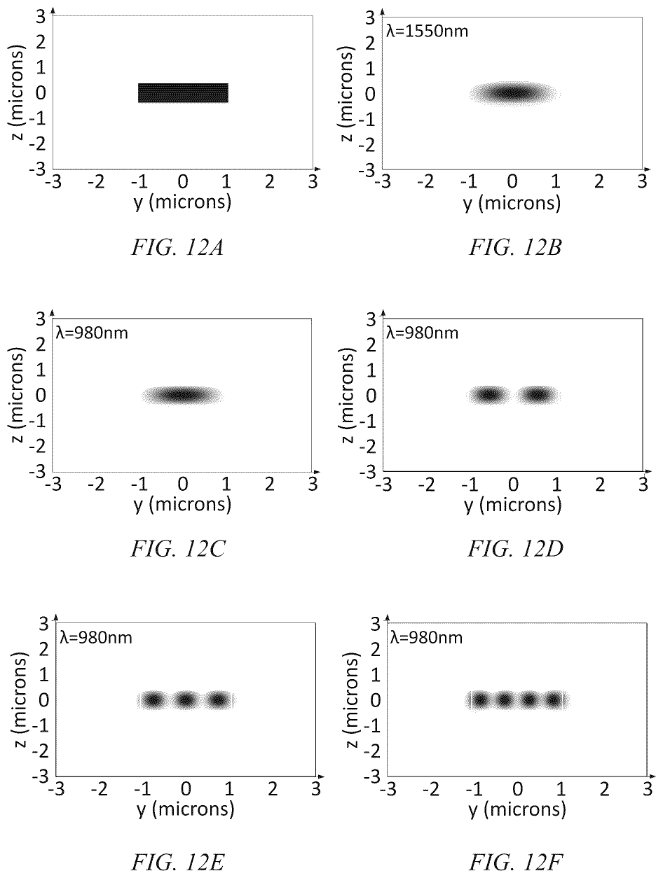

There are various possible implementations of the multi-mode gain waveguide 1100. One type, depicted with a plot of refractive index values in FIG. 12A, is a multi-mode waveguide with a single waveguide core. A cross-section of the waveguide core is plotted. FIG. 12A represents a strip waveguide, but the multi-mode gain waveguide 1100 could also be a rib or ridge waveguide.

The multi-mode gain waveguide 1100 can support various TE and TM spatial modes. An example TE fundamental mode at the signal wavelength is depicted in FIG. 12B. However, any mode of the waveguide can be used for the signal wavelength as long as only one mode is excited, in some implementations. (If the output signal is intended to be incoherent, then multiple optical modes can be excited.) FIG. 12C, FIG. 12D, FIG. 12E, and FIG. 12F plot higher-order TE spatial modes at the pump wavelength (980 nm in this example). Different sets of pump modes could be chosen for excitation of the gain waveguide 1100 (e.g., a set including TM modes), but the plotted set of TE modes are readily excited for some implementations of the signal and pump combiner 1020 depicted in FIG. 10. The waveguide profile depicted in FIG. 12A can confine the signal mode and the pump modes within the same waveguide core, enabling a high overlap between optical modes of the gain radiation, signal radiation, and the rare-earth ions which may be in the core of the gain waveguide 1100.

### 4. Multimode Beams

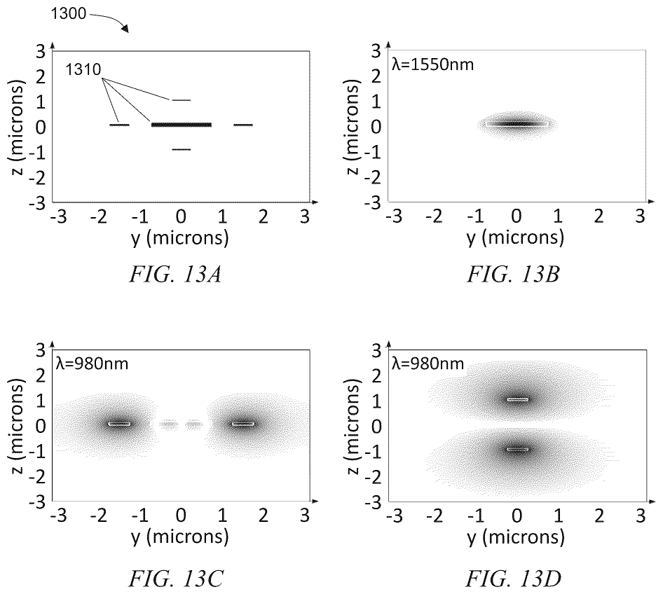

Another implementation of the multi-mode gain waveguide 1300 is depicted with the plot of refractive index values in FIG. 13A. In this case, the multi-mode gain waveguide 1300 comprises multiple waveguide cores 1310 (five in the illustrated example) where each core is surrounded by cladding material. The five waveguide cores can be formed from three vertical layers of patterned core material. The larger central waveguide core can guide the signal beam, and the four smaller outer waveguide cores can guide pump radiation. However, any number of vertical layers could be used, including one, as long as more than one core is formed. In some implementations, there can be three waveguide cores (eg., the larger central core and only the two waveguide cores for pump radiation above and below the central core. Pump radiation can couple to the larger central core from the smaller waveguide cores to excite dopants in the central core for optical gain of the signal beam. In some implementations, dopants can additionally or alternatively be in the cladding around the central waveguide to provide optical gain for the evanescent field outside the central waveguide.

FIG. 13B plots an example signal mode which is the fundamental TE mode within the central core of FIG. 13A. The outline of the core is illustrated with a black rectangle. FIG. 13C and FIG. 13D plot examples of pump modes in the adjacent pump waveguides. Due to the symmetry of the waveguide array illustrated, these outer pump modes can be symmetric and/or antisymmetric modes distributed across the outer cores. The pump modes utilized within this type of multi-mode gain waveguide are confined to different cores than the central core that confines the signal mode. This enables a multi-mode high power pump to be distributed across a large area to support high amplifier output powers. The rare-earth ions or other dopants for gain could be within the core that guides the signal mode, and/or in the surrounding cladding, as long as both the pump modes and the signal mode have some simultaneous overlap with the dopants.

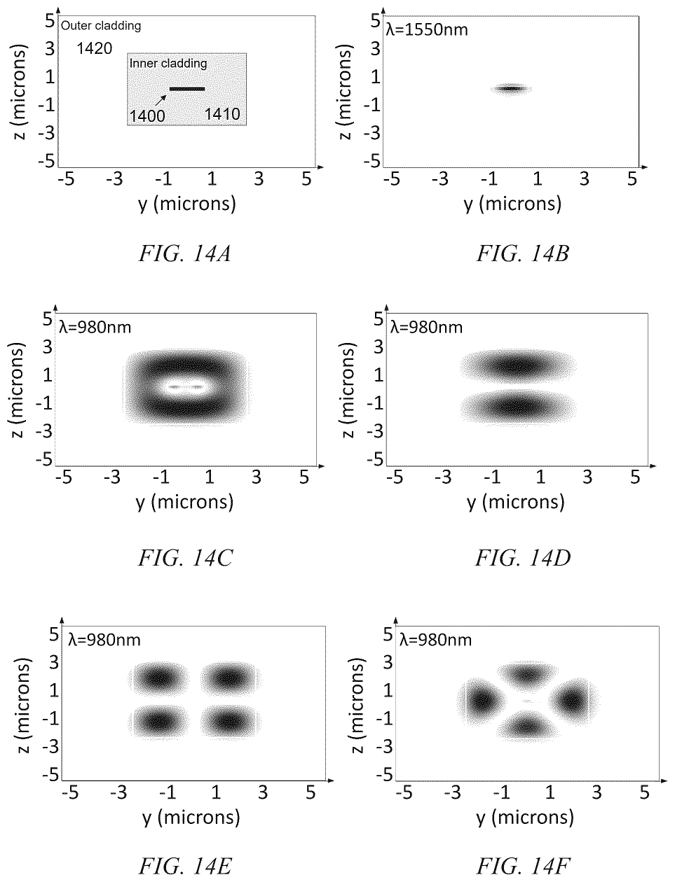

In some implementations, the multi-mode gain waveguide 1400 can support higher-order pump modes around a central core for the signal radiation. Such implementations can use two cladding materials, as depicted with the plot of refractive index in FIG. 14A. In this implementation, a first cladding material 1410 surrounds the core of the gain waveguide 1400 and a second cladding material 1420 surrounds the first cladding material. The refractive index value of the first cladding material 1410 is greater than the refractive index value of the second cladding material 1420. FIG. 14B plots an example spatial mode of the signal beam which is the fundamental TE mode within the gain waveguide 1400. FIG. 14C, FIG. 14D, FIG. 14E, and FIG. 14F plot examples of higher-order pump modes that can propagate along the gain waveguide 1400 around the central core. The pump modes are confined, at least in part, by the inner, first cladding material 1410. The confinement of the pump modes over larger area enables a multi-mode, high-power pump to be distributed across a large area to support high amplifier output powers. The rare-earth ions or other dopants could be within the core that the signal mode propagates in, and/or in the surrounding cladding(s), as long as both the pump modes and the signal mode have some simultaneous overlap with the dopants. Additional double-clad waveguide configurations can achieve a similar effect of pump mode confinement around a central core that carries the signal beam, such as geometries in which one or both claddings are asymmetric in geometry or index profile.

### 5. Multi-Stage Optical Amplifiers

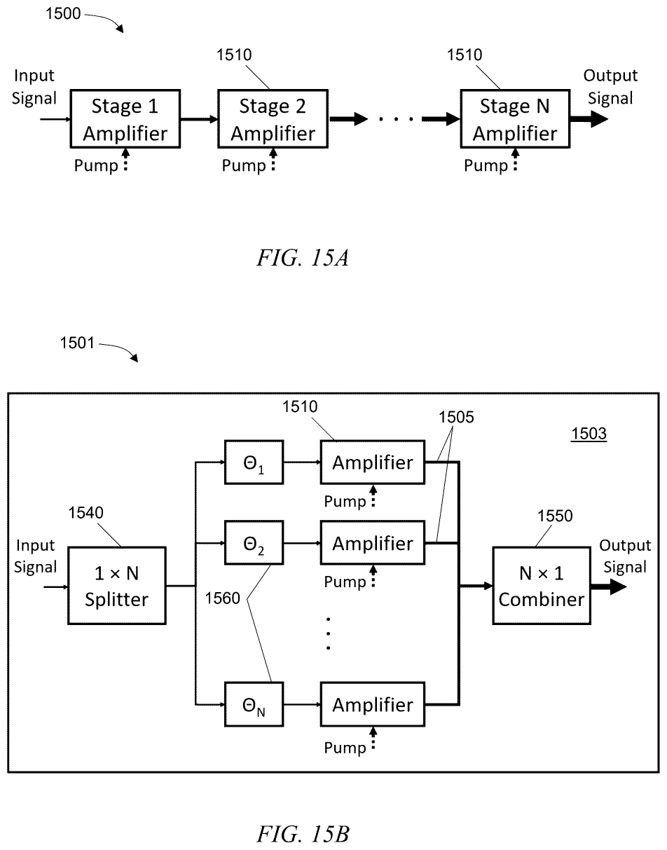

An additional way to increase optical output power for an optical amplifier is to use two or more cascaded amplifier stages in an optical amplifier system 1500, as depicted in FIG. 15A. These stages may or may not be identical. Any of the optical amplifier stages depicted in FIG. 15A through FIG. 20E can comprise any of the above-described gain waveguide configurations as well as beam combiners and mode converters.

An initial high-gain stage can be followed by a high-power saturation stage to provide low noise and high output powers. By altering the characteristics of each amplifier stage, such as gain in the gain waveguide, pump power/current, and pump wavelength, the performance of each stage can be tuned for improved performance and increased output powers. For an optical amplifier with cascaded stages, the noise figure of the first stage dominates the overall noise figure of the amplifier. Using a low-noise first stage with relatively low gain followed by a noisier second stage with higher gain can make it possible to achieve high gain with relatively good noise performance.

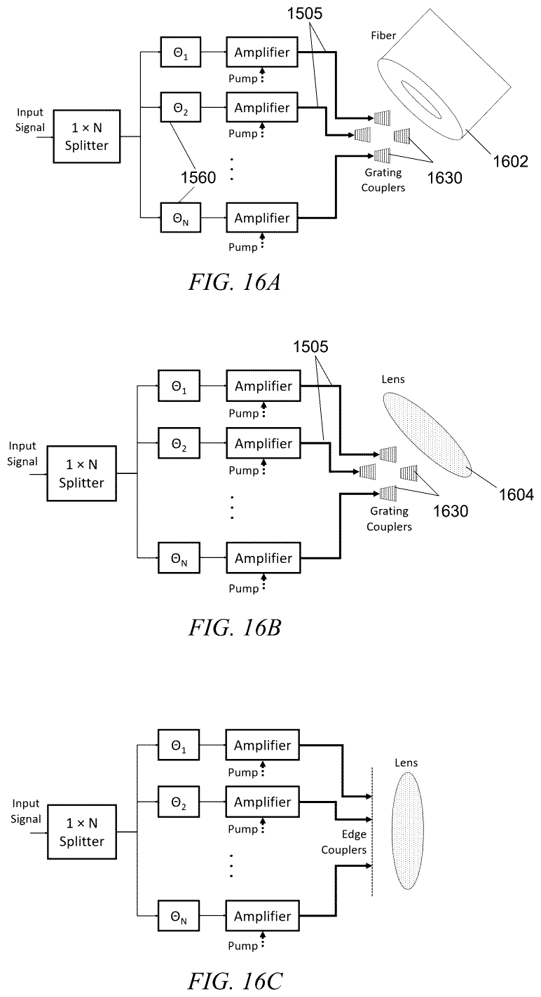

Another method to increase output power is to utilize parallel amplifier stages in an optical amplifier system 1501, as depicted in FIG. 15B. In this configuration, a single input signal is distributed to two or more amplifier arms 1505 through a 1×N coupler 1540, where N is an integer greater than 1. The 1×N coupler 1540 is in optical communication with the input to each amplifier arm 1505 and each optical amplifier 1510. Each amplifier arm 1505 need not be identical and could also contain cascaded, or even parallel, amplifiers 1510 within it. One implementation for an optical amplifier system in which the optical amplifiers 1510 are connected in parallel is to coherently combine the optical outputs from the amplifier arms 1505 into a single output, such as a waveguide, using an N×1 combiner 1550. To combine outputs from each amplifier arm 1505 with the same optical phase, an optical phase shifter 1560 can be placed within each amplifier arm 1505 or some of the amplifier arms (eg., all but one). The phase shifter 1560 could be active (eg., thermo-optic, electro-optic, plasma dispersion, MEMS, acousto-optic, etc.) or passive and could be placed before or after the amplifier 1510 within the amplifier arm 1505. The phase shifter in each amplifier arm 1505 is in optical communication with the optical amplifier 1510 in the corresponding arm and with the gain waveguide in the optical amplifier. Each phase shifter 1560 is configured to modulate the phase of the signal beam passing through the phase shifter. The optical components in FIG. 15B (and in the drawings of FIG. 16A through FIG. 20E (except for the optical fibers in some cases) can be formed on a chip 1503 comprising cladding material and a substrate, as described elsewhere herein.

For some applications, it can be beneficial to coherently combine the optical outputs from the amplifier arms 1505 into structures other than waveguides due to nonlinear losses, catastrophic optical damage, and/or for integration into a larger optical system. FIG. 16A depicts a configuration where the optical outputs from the amplifier arms 1505 are coherently combined into an optical fiber 1602. The coupling to the optical fiber can be done using grating couplers 1630, edge couplers, optical phased arrays, or other integrated couplers. Various output fiber types are possible such as single-mode fibers, large-mode area fibers, photonic crystal fibers, few-mode fibers, hollow-core fibers, and others.

The optical outputs from the amplifier arms 1505 can also be coherently combined in free space to enable large output powers. The output radiation from each of the amplifier arms 1505 can emitted from the chip to free space (eg., using grating couplers) and combined to form a single output. This radiation can be collimated in free space using an external lens 1604. This lens could be a spherical, aspherical, reflective, compound, or flat lens. The lens 1604, which can focus in two dimensions, is coupled to a grid of on-chip optical emitters (implemented as grating couplers 1630 in FIG. 16B). Alternatively, the lens could be a cylindrical, reflective, compound, or flat lens with focusing power in one dimension that is coupled to a linear array of on-chip optical emitters (as depicted in FIG. 16C). If the on-chip optical emitters form a large enough aperture, such as in an optical phased array or a large-area grating coupler, a lens may not be required to collimate the radiation-the radiation can be coupled directly from the chip to the optical fiber or other structure.

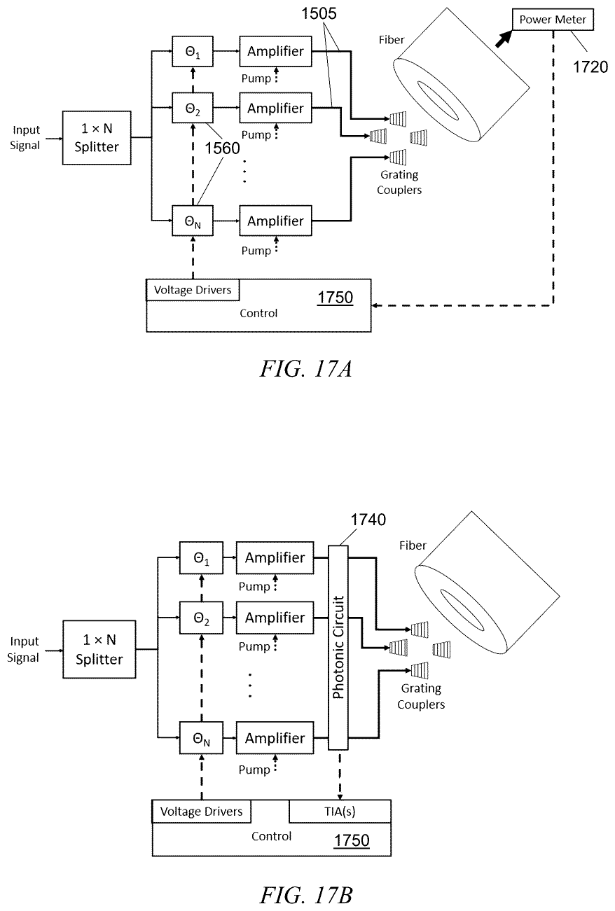

When coherently combining the optical outputs from the amplifier arms 1505 into a structure such as a fiber, lens, waveguide, or free space beam, the phase shifters 1560 in each or some of the amplifier arms 1505 can be tuned dynamically to account for drifts in optical phase due to temperature changes, amplifier noise, mechanical perturbations, or free space perturbations. FIG. 17A depicts an implementation where the output power after combining from the amplifier arms 1505 into a receiving optical structure is sampled by a detector 1720 and used for feedback to control, by a controller 1750, the optical phase shifters 1560. The measured output power may be tapped off from a main output using a directional coupler, beam splitter, evanescent coupler, or other optical tap component. To set the optical phase shifters 1560 to produce the desired output power (which may be a global maximum value as a function of the different phase setting combinations), various algorithms such as hill-climbing, gradient descent, stochastic gradient descent, phase retrieval, or other methods can be utilized.

Alternatively, a photonic circuit 1740 that measures the arm amplitudes or phases could be utilized for feedback to the controller 1750 during phase shifter control (as illustrated in FIG. 17B). Various on-chip phase detection photonic circuits are possible such as photodetection, coherent detectors between adjacent arms, or combining the arms into a photodetector.

Additionally, when coherently combining the optical outputs from the amplifier arms 1505 into a receiving optical structure such as a fiber, lens, waveguide, or even into free space, it may be desirable to produce a non-uniform amplitude profile from the output couplers. The non-uniform amplitude emission profile depends on the optical structure being coupled to and its preferred input mode profile. For higher coupling efficiency, the emission profile of the combined optical outputs from the amplifier arms 1505 should match or approximate the input mode profile preferred by the receiving optical structure. Gaussian modes are commonly preferred spatial modes for many optical fibers, lenses, waveguides, and free-space beams but other profiles could be possible such as Hermite-Gaussian modes, Laguerre-Gaussian modes, or Bessel modes.

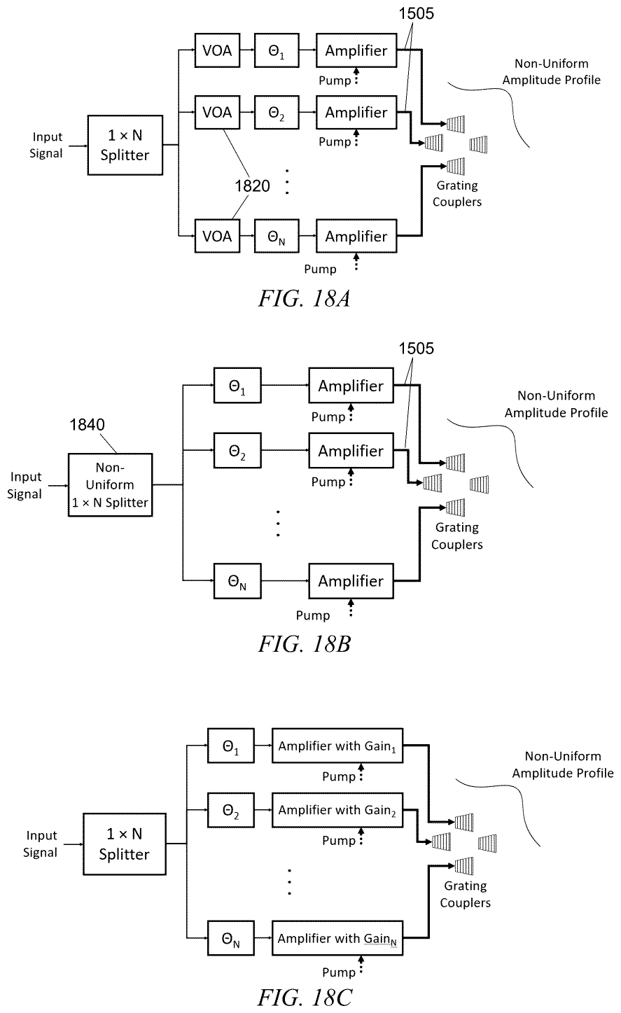

The system configuration of FIG. 18A illustrates one implementation for outputting a desired spatial mode profile. To match or approximate the desired non-uniform output profile, the amplifier arms 1505 can output different amplitudes. In one implementation, this is accomplished with a variable optical attenuator (VOA) 1820 in some or all amplifier arms 1505. Alternatively, a statically set loss structure can be set in some or all amplifier arms 1505 for a static output mode profile. These implementations utilize optical loss to produce the desired non-uniform amplitude profile with the combined output from the amplifier arms 1505.

The implementation depicted in FIG. 18B utilizes a non-uniform 1×N splitter 1840 to split the input signal to the N amplifier arms such that at least some or all of the amplifier arms have a different input power and thus output power assuming a constant amplifier gain across the amplifier arms 1505. The non-uniform 1×N splitter could be static or dynamically set and formed by a star coupler, Mach-Zehnder switch network, cascaded directional couplers, a binary tree of non-uniform 1×2 splitters, or other configurations. For example, the binary tree of non-uniform 1×2 splitters could be used to produce a static output from the 1×N splitter and the Mach-Zehnder switch network could be used to dynamically vary the output from the 1×N splitter. In the example cases described in this paragraph, there can be no significant additional loss added to the parallel amplifiers to produce a non-uniform amplitude profile.

Instead of having a non-uniform input power to at least some of the amplifier arms, a non-uniform gain across the amplifier arms enables the output to have a non- uniform amplitude profile (FIG. 18C). To produce different gains between at least some or all of the amplifier arms, each amplifier or some of the amplifiers could be pumped with a different input power or current, the amplifier length could be different, or have a different overall underlying design. The non-uniform amplitude profile at the output can be static (fixed gains, fixed splitting ratios) or dynamic (e.g., varying the pump input powers or currents for the gain sections).

For each method that produces a non-uniform output amplitude profile, along with those not specified, feedback for dynamic elements such as the VOAs, non-uniform splitter, amplifier gain, or others can occur through feedback techniques discussed above and depicted in FIG. 17A and FIG. 17B. That is, the output powers from the amplifier arms 1505 can be tuned through feedback by measuring the coherently combined output signal or by a photonic circuit that determines the amplitude in each amplifier arm 1505.

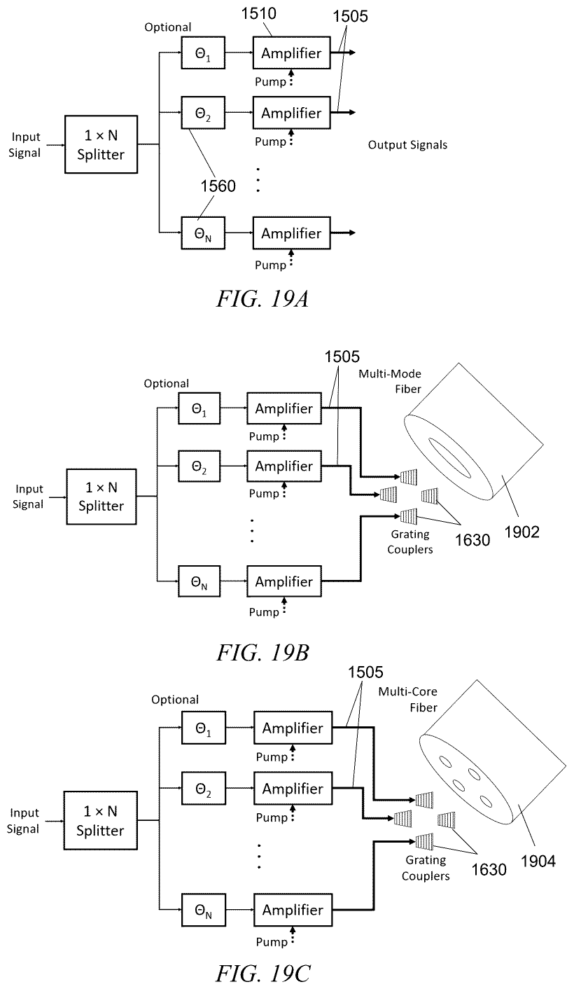

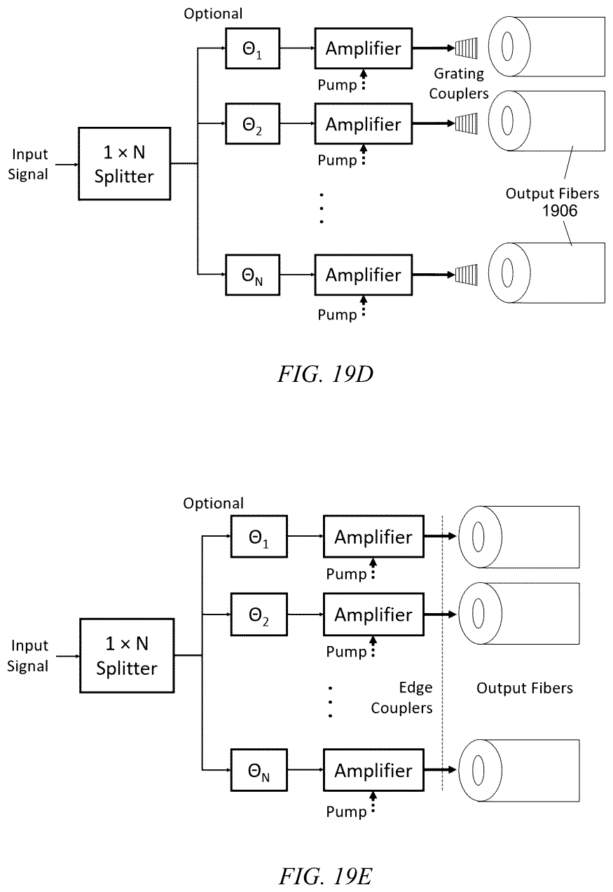

Some implementations coherently combine parallel optical outputs from the amplifier arms 1505. Coherent combination can enable a high-brightness output due to its single-mode operation. However, for very high optical output powers, this high brightness can be too intense for certain optical mediums and cause catastrophic optical damage. Alternatively, in some implementations the parallel amplifier arms can be combined incoherently into multiple modes or separate receiving optical structures. FIG. 19A depicts such a configuration with a single input signal that is split across N amplifier arms 1505. At least some or all of the amplifier arms 1505 have an optional optical phase shifter 1560 and an integrated optical amplifier 1510. In this case, the outputs of each amplifier arm 1505 are not combined coherently but the total output power of the amplifier system can be large due to the parallel amplifiers 1510.

The output power from the amplifier arms 1505 can be coupled into a variety of multi-mode optical structures. FIG. 19B depicts the optical output from the amplifier arms 1505 being coupled to a multi-mode optical fiber 1902 through on-chip grating couplers 1630. The radiation emitted from the on-chip grating couplers 1630 is not coherently combined into a single mode but can be completely captured by the multi-mode optical fiber 1902 (that is in optical communication with the grating couplers) and distributed across its multiple spatial optical modes. This approach to amplification and output coupling enables guiding and further use of the high-power output of the integrated optical amplifier system without the need for coherent combination. The multi-mode optical fiber 1902 could be formed in a variety of ways such as a large core or a photonic crystal fiber. Instead of optical fiber, the emitted radiation from the amplifier arms could form a multi-mode, free-space optical beam which may be incident to an optical lens or lensing system, for example.

In some implementations, the radiation from at least some or all of the amplifier arms may be coupled to a corresponding guiding optical structure instead of a single multi-mode structure. FIG. 19C depicts each amplifier arm being coupled to a corresponding core of a multi-core optical fiber 1904. There may be one core for each amplifier arm 1505, though other arrangements are also possible. Each of the cores of the multi-core optical fiber 1904 can be a single-mode or multi-mode core. Unlike in other implementations, the outputs from each amplifier arm 1505 do not combine or interact with each other after emission from the output couplers at the ends of the amplifier arms 1505 and when propagating along the multi-core optical fiber 1904. Though grating couplers 1630 are illustrated in FIG. 19C and other drawings herein, it is also possible to couple to a multi-core optical fiber 1904 or multi-mode optical fiber 1902 using edge couplers on multiple vertical waveguide levels. Instead of a multi-core optical fiber 1902, individual optical fibers 1906 or a fiber array could be utilized with grating couplers (FIG. 19D) or edge couplers (FIG. 19E). Furthermore, for parallel amplifier arms 1505 with a single input and multiple outputs, the on-chip coupling mechanism, or the coupling structure itself, need not be the same between the input or outputs, between the outputs, or the individual signals that comprise them.

### 6. Multi-Channel Optical Amplifiers

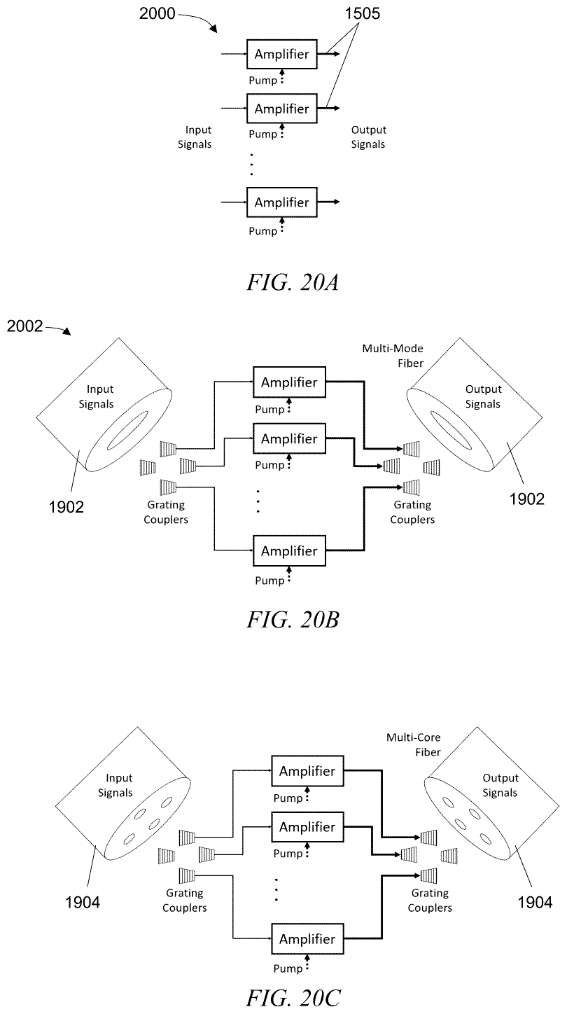

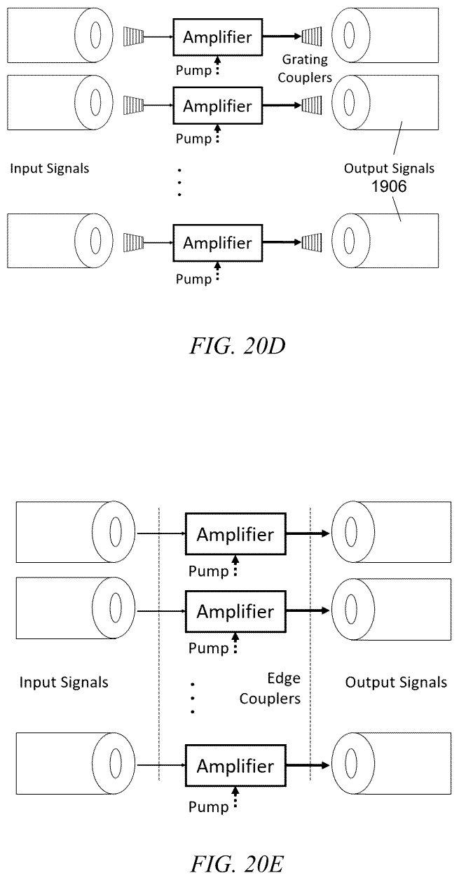

FIG. 20A depicts an implementation of a multi-channel integrated optical amplifier system 2000 comprising parallel amplifier arms 1505, each with a corresponding optical input and optical output. The multi-channel integrated optical amplifier system 2000 can support a large total output power due to the parallel amplifier arms 1505. The optical inputs and outputs can be coupled on and off chip with various couplers such as grating couplers and edge couplers.

The possible optical structures that can be coupled to the multiple inputs and/or to the multiple outputs of the amplifier arms 1505 are similar to optical structures described in previous implementations, such as a multi-mode optical fiber 1902 (FIG. 20B). When coupling to a multi-mode optical fiber 1902 at the inputs to the multi-channel integrated optical amplifier system 2000, it is not necessary that each optical mode from the input optical structure 2002 couples to an amplifier arm 1505 (e.g., when there are potentially more input modes in the input multi-mode optical fiber 1902 than amplifier arms 1505). If coupling selected input optical modes to an amplifier arm 1505 is desired, the multi-channel integrated optical amplifier system 2000 can use an M x N photonic circuit that maps the input modes from the input optical structure 2002 (a multi-mode optical fiber 1902 in the illustrated example of FIG. 20B) to the inputs of the amplifier arms 1505 such that each optical mode from the input optical structure 2002 can be routed to a single amplifier arm 1505. The resulting optical assembly with the M×N photonic circuit disposed between the input optical structure 2002 and the inputs to the amplifier arms 1505 can form a mode-selective amplifier. Depending on the input optical structure 2002 and number of modes it provides, it may be possible to position or design the input couplers to the amplifier arms 1505 to correctly route the input modes to single corresponding amplifier arms without an additional photonic circuit (eg., when the input optical structure 2002 provides N input modes and there are N amplifier arms 1505).

In some implementations, the radiation to and from at least some of the amplifier arms may be separately coupled to a corresponding optical guiding structure instead of combined into multi-mode optical fiber. FIG. 20C depicts at least some of the amplifier arms 1505 being coupled to and from separate cores of a multi-core optical fibers 1904. As described above, though grating couplers are illustrated, it is also possible to couple to and from a multi-core optical fiber 1904 using edge couplers on multiple vertical waveguide levels. Instead of a multi-core optical fiber, individual optical fibers 1906 or a fiber array can be utilized with grating couplers (FIG. 20D) or edge couplers (FIG. 20E). Furthermore, for parallel amplifier arms with multiple inputs and multiple outputs, the on-chip coupling mechanism, or the coupling structure itself, need not be the same between the inputs or outputs, between inputs, between outputs, or the individual signals that comprise them.

The gain sections, gain waveguides, and optical amplifiers described herein can be configured to provide optical gain to radiation (such as signal radiation) having a peak wavelength (highest intensity wavelength) from 400 nm to 3 microns and a bandwidth from 1 nm to 100 nm. The gain sections, gain waveguides, and optical amplifiers may support only a fundamental optical mode at the peak wavelength of the radiation that is amplified in the gain section or optical amplifier. The pump radiation described herein can have a peak wavelength from 500 nm to 2 microns. The pump waveguides may support only a fundamental optical mode at the peak wavelength of the pump radiation. In some implementations, the pump waveguides may support at least one higher-order optical mode at the peak wavelength of the pump radiation.

### 7. Conclusion

While various inventive implementations have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive implementations described herein. M ore generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive implementations described herein. It is, therefore, to be understood that the foregoing implementations are presented by way of example only and that, within the scope of the appended claims and equivalents thereto, inventive implementations may be practiced otherwise than as specifically described and claimed. Inventive implementations of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, implementations may be constructed in which acts are performed in an order different than illustrated, which may include performing some acts simultaneously, even though shown as sequential acts in illustrative implementations.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the components so conjoined, i.e., components that are conjunctively present in some cases and disjunctively present in other cases. Multiple components listed with “and/or” should be construed in the same fashion, i.e., “one or more” of the components so conjoined. Other components may optionally be present other than the components specifically identified by the “and/or” clause, whether related or unrelated to those components specifically identified. Thus, as a non-limiting example, a reference to “A and/or B”, when used in conjunction with open-ended language such as “comprising” can refer, in one implementation, to A only (optionally including components other than B); in another implementation, to B only (optionally including components other than A); in yet another implementation, to both A and B (optionally including other components); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of components, and, optionally, additional unlisted items. Only terms clearly indicated to the contrary, such as “only one of” or “exactly one of,” or, when used in the claims, “consisting of,” will refer to the inclusion of exactly one component of a number or list of components. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more components, should be understood to mean at least one component selected from any one or more of the components in the list of components, but not necessarily including at least one of each and every component specifically listed within the list of components and not excluding any combinations of components in the list of components. This definition also allows that components may optionally be present other than the components specifically identified within the list of components to which the phrase “at least one” refers, whether related or unrelated to those components specifically identified. Thus, as a non-limiting example, “at least one of A and B” (or, equivalently, “at least one of A or B,” or, equivalently “at least one of A and/or B”) can refer, in one implementation, to at least one, optionally including more than one, A, with no B present (and optionally including components other than B); in another implementation, to at least one, optionally including more than one, B, with no A present (and optionally including components other than A); in yet another implementation, to at least one, optionally including more than one, A, and at least one, optionally including more than one, B (and optionally including other components); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An integrated optical amplifier comprising:
a substrate; and
a first waveguide integrated with the substrate and having a gain section of length L_{g} that is doped with rare-earth ions or transition metal ions, wherein:
the first waveguide is configured to guide a pump beam and guide a signal beam,
the first waveguide is further configured to amplify the signal beam when the rare-earth ions or the transition metal ions are excited with the pump beam, and
the gain section is configured to provide an amount of gain per unit length that changes with distance along the length L_{g} of the gain section or reduce or maintain an intensity level of the signal beam along the length L_{g} of the gain section to reduce or avoid gain saturation in the gain section.

2. The integrated optical amplifier of claim 1, wherein at least one of a cross-sectional dimension of the gain section or a doping level of the rare-earth ions or the transition metal ions change as a function of the distance along the length L_{g} of the gain section to change the gain per unit length in the gain section.

3. The integrated optical amplifier of claim 2, wherein the gain section is tapered in at least one cross-sectional dimension along at least a portion of the length L_{g} of the gain section.

4. The integrated optical amplifier of claim 1, wherein the first waveguide comprises SiN.

5. The integrated optical amplifier of claim 1, wherein the first waveguide has a propagation loss of no greater than 10 dB/m at a wavelength of the signal beam.

6. The integrated optical amplifier of claim 1, wherein the first waveguide is configured to guide multiple spatial modes at a wavelength of the pump beam.

7. The integrated optical amplifier of claim 1 wherein the first waveguide comprises a core, a first cladding disposed about the core, and a second cladding disposed about the first cladding.

8. The integrated optical amplifier of claim 7, wherein:
the core supports a fundamental mode of the signal beam; and
the first cladding supports higher-order modes of the pump beam.

9. The integrated optical amplifier of claim 1, further comprising:
a second waveguide integrated with the substrate and having a section parallel to the gain section of the first waveguide, wherein the second waveguide is configured to evanescently couple the signal beam from the gain section along at least a portion of the length L_{g} of the gain section and thereby reduce gain saturation in the gain section.

10. The integrated optical amplifier of claim 1, further comprising:
a second waveguide integrated with the substrate and having a section parallel to the gain section of the first waveguide, to evanescently couple the pump beam into the gain section.

11. An integrated optical amplifier system comprising:
a substrate; and
a plurality of optical amplifiers disposed on the substrate, each optical amplifier comprising:
an input to receive at least a signal beam to be amplified;
a gain waveguide coupled to the input and integrated with the substrate and having a gain section of length L_{g} that is doped with rare-earth ions or transition metal ions; and
an output to output an amplified signal beam, wherein:
the gain section is configured to guide a pump beam and guide the signal beam and to amplify the signal beam, producing the amplified signal beam when the rare-earth ions or the transition metal ions are excited with the pump beam, and
the gain section is configured to provide an amount of gain per unit length that changes with distance along the length L_{g} of the gain section or reduce or maintain an intensity level of the signal beam along the length L_{g} of the gain section to reduce or avoid gain saturation in the gain section.

12. The integrated optical amplifier system of claim 11, wherein the gain waveguide is a first waveguide of each optical amplifier, at least one optical amplifier of the plurality of optical amplifiers further comprising:
a second waveguide integrated with the substrate and having a section parallel to the gain section of the first waveguide, wherein the second waveguide is configured to evanescently couple the signal beam from the gain section along at least a portion of the length L_{g} of the gain section and thereby reduce gain saturation in the gain section.

13. The integrated optical amplifier system of claim 11, wherein the plurality of optical amplifiers comprises N optical amplifiers connected in parallel, where N is an integer greater than 1, and further comprising:
a 1×N coupler, integrated with the substrate and in optical communication with the input to each optical amplifier of the plurality of optical amplifiers, to couple the signal beam to the input of each optical amplifier.

14. The integrated optical amplifier system of claim 13, wherein:
the 1×N coupler is further configured to couple the pump beam to the input of each optical amplifier of the plurality of optical amplifiers.

15. The integrated optical amplifier system of claim 11, wherein at least one optical amplifier of the plurality of optical amplifiers further comprises:
a phase shifter in optical communication with the gain waveguide to modulate a phase of the signal beam when the signal beam passes through the phase shifter.

16. The integrated optical amplifier system of claim 11, wherein each output comprises a grating coupler or an edge coupler to emit the amplified signal beam from the substrate.

17. The integrated optical amplifier system of claim 16, further comprising:
a multimode waveguide, in optical communication with the grating coupler or the edge coupler, to receive the amplified signal beam and combine the amplified signal beam with other amplified signal beams from other optical amplifiers of the plurality of optical amplifiers.

18. The integrated optical amplifier system of claim 16, further comprising:
a multi-core optical fiber, in optical communication with the grating coupler or the edge coupler, to receive the amplified signal beam into one core of the multi-core optical fiber such that the received amplified signal beam does not combine with other amplified signal beams from other optical amplifiers of the plurality of optical amplifiers.

19. The integrated optical amplifier system of claim 16, further comprising:
a single mode optical fiber, in optical communication with the grating coupler or the edge coupler, to receive the amplified signal beam such that the received amplified signal beam does not combine with other amplified signal beams from other optical amplifiers of the plurality of optical amplifiers.

20. An integrated optical amplifier comprising:
a substrate;
a first waveguide integrated with the substrate and having a gain section of length L_{g} that is doped with rare-earth ions or transition metal ions, wherein the first waveguide is configured to guide a pump beam and guide a signal beam and to amplify the signal beam when the rare-earth ions or the transition metal ions are excited with the pump beam; and
a second waveguide integrated with the substrate and having a section parallel to the gain section of the first waveguide, wherein the second waveguide is configured to evanescently couple the signal beam from the gain section along at least a portion of the length L_{g} of the gain section and thereby reduce gain saturation in the gain section.
